(19) United States
(12) Patent Application Publication
(10) Pub. No.: US 2025/0221242 A1
(43) Pub. Date: Jul. 3, 2025

(54) DISPLAY PANEL AND MANUFACTURING METHOD THEREFOR, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Changlong YUAN, Beijing (CN); Li ZHU, Beijing (CN); Zhenhua ZHANG, Beijing (CN); Tong WU, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/851,088

(22) PCT Filed: Oct. 19, 2023
(86) PCT No.: PCT/CN2023/125360

§ 371 Date: Sep. 26, 2024

(30) Foreign Application Priority Data
Nov. 29, 2022 (CN) 202211510549.6

(51) Int. Cl. H10K 59/80; H10K 59/12; H10K 59/35; H10K 59/60; H10K 71/00; H10K 71/60; H10K 102/00

(52) U.S. Cl. CPC H10K 59/80523; H10K 59/1201; H10K 59/60; H10K 59/80522; H10K 71/60; H10K 71/621; H10K 59/353; H10K 2102/351

(57) ABSTRACT

A display panel (100), comprising a substrate (11), an anode layer (12), a cathode layer (13), a light-emitting portion (14) and a photoelectric conversion portion (15). The anode layer (12) is arranged on one side of the substrate (11), and the anode layer (12) comprises a first electrode (121) and a second electrode (122). The cathode layer (13) is arranged on the side of the anode layer (12) that is away from the substrate (11), and the cathode layer (13) comprises a third electrode (131) and a fourth electrode (132), wherein the third electrode (131) is arranged opposite the first electrode (121) and the fourth electrode (132) is arranged opposite the second electrode (122), and the thickness of the third electrode (131) is greater than the thickness of the fourth electrode (132) in a direction perpendicular to the substrate (11). The light-emitting portion (14) is arranged between the first electrode (121) and the third electrode (131). The photoelectric conversion portion (15) is arranged between the second electrode (122) and the fourth electrode (132).

### CROSS-REFERENCE TO RELATED APPLICATIONS

This application is a national phase entry under 35 USC 371 of International Patent Application No. PCT/CN2023/125360 filed on Oct. 19, 2023, which claims priority to Chinese Patent Application No. 202211510549.6, filed on Nov. 29, 2022, which are incorporated herein by reference in their entirety.

### TECHNICAL FIELD

The present disclosure relates to the field of display technologies, and in particular, to a display panel and a manufacturing method therefor, and a display apparatus.

### BACKGROUND

With the rapid development of display technologies, display apparatuses have gradually come throughout people's lives. Among them, organic light-emitting diodes (OLEDs) are widely used in smart products such as mobile phones, televisions, and notebook computers owing to their advantages of self-luminescence, low power consumption, wide viewing angle, high response speed, high contrast, and flexible display.

### SUMMARY

In an aspect, a display panel is provided. The display panel includes a substrate, an anode layer, a cathode layer, a light-emitting portion, and a photoelectric conversion portion. The anode layer is disposed on a side of the substrate and includes a first electrode and a second electrode. The cathode layer is disposed on a side of the anode layer away from the substrate and includes a third electrode and a fourth electrode. The third electrode is disposed opposite to the first electrode, and the fourth electrode is disposed opposite to the second electrode; and along a direction perpendicular to the substrate, a thickness of the third electrode is greater than a thickness of the fourth electrode. The light-emitting portion is disposed between the first electrode and the third electrode. The photoelectric conversion portion is disposed between the second electrode and the fourth electrode.

In some embodiments, along the direction perpendicular to the substrate, the cathode layer includes a first sub-layer and a second sub-layer, the first sub-layer being located on a side of the second sub-layer proximate to the substrate; and along the direction perpendicular to the substrate, the third electrode includes a first sub-electrode and a second sub-electrode arranged in a stack, the first sub-electrode being located in the first sub-layer, and the second sub-electrode being located in the second sub-layer; and the fourth electrode is located in the first sub-layer.

In some embodiments, the display panel further includes a first peeling portion, disposed on a side of the fourth electrode away from the substrate. Adhesion between the first peeling portion and the second sub-layer is less than adhesion between the first sub-layer and the second sub-layer.

In some embodiments, the cathode layer further includes an auxiliary cathode, the auxiliary cathode being electrically connected to the third electrode, the fourth electrode and a common voltage terminal in the display panel; and along the direction perpendicular to the substrate, a thickness of the auxiliary cathode is greater than a thickness of the third electrode.

In some embodiments, the cathode layer includes a first sub-layer, a second sub-layer and a third sub-layer, the first sub-layer being located on a side of the second sub-layer proximate to the substrate, and the third sub-layer being located on a side of the second sub-layer away from the substrate; and along the direction perpendicular to the substrate, the auxiliary cathode includes a first conductive pattern, a second conductive pattern and a third conductive pattern arranged in a stack, the first conductive pattern being located in the first sub-layer, the second conductive pattern being located in the second sub-layer, and the third conductive pattern being located in the third sub-layer.

In some embodiments, the display panel further includes a second peeling portion, disposed on a side of the third electrode away from the substrate. Adhesion between the second peeling portion and the third sub-layer is less than adhesion between the second sub-layer and the third sub-layer.

In some embodiments, the display panel further includes a first peeling portion. The first peeling portion and the second peeling portion partially overlap, and a portion of the second peeling portion overlapping with the first peeling portion is located on a side of the first peeling portion away from the substrate.

In some embodiments, the display panel further includes a first peeling portion. The first peeling portion includes a first sub-portion and a second sub-portion arranged in a stack, the first sub-portion being located on a side of the second sub-portion proximate to the substrate, and the second sub-portion and the second peeling portion being made of a same material and disposed in a same layer.

In some embodiments, the display panel further includes a first peeling portion, a maximum area of an orthographic projection of the first peeling portion on the substrate being less than a maximum area of an orthographic projection of the second peeling portion on the substrate.

In some embodiments, the display panel further includes a first peeling portion, and the display panel further includes a pixel defining layer disposed on a side of the anode layer away from the substrate, the pixel defining layer being provided with a pixel opening and a light-sensing opening. The first peeling portion covers a bottom of the light-sensing opening and extends to a surface of the pixel defining layer away from the substrate; and the second peeling portion covers a bottom of the pixel opening and extends to the surface of the pixel defining layer away from the substrate.

A portion of the first peeling portion extending to the surface of the pixel defining layer away from the substrate is a first portion, and a portion of the second peeling portion extending to the surface of the pixel defining layer away from the substrate is a second portion; and an average distance between a boundary of the first portion and the light-sensing opening is less than an average distance between a boundary of the second portion and the pixel opening.

In some embodiments, the display panel further includes a functional layer, including a light-emitting functional portion and a photoelectric functional portion, the light-emitting functional portion being disposed between the first electrode and the third electrode, and the photoelectric functional portion being disposed between the second electrode and the fourth electrode.

In some embodiments, an overlapping portion of the first electrode, the light-emitting portion and the third electrode forms a light-emitting device; and the display panel includes a plurality of light-emitting devices which include a plurality of red light-emitting devices, a plurality of blue light-emitting devices, a plurality of first green light-emitting devices, and a plurality of second green light-emitting devices.

The plurality of red light-emitting devices and the plurality of blue light-emitting devices are arrayed into multiple rows and multiple columns, each row includes multiple red light-emitting devices and multiple blue light-emitting devices that are arranged in a staggered manner along a first direction, and each column includes multiple red light-emitting devices and multiple blue light-emitting devices that are arranged in a staggered manner along a second direction.

The plurality of first green light-emitting devices and the plurality of second green light-emitting devices are arrayed into multiple rows and multiple columns, each row includes multiple first green light-emitting devices and multiple second green light-emitting devices that are arranged in a staggered manner along the first direction, each column includes multiple first green light-emitting devices and multiple second green light-emitting devices that are arranged in a staggered manner along the second direction; and a first green light-emitting device in the plurality of first green light-emitting devices is located between red and blue light-emitting devices arranged in two adjacent rows and two adjacent columns, and a second green light-emitting device in the plurality of second green light-emitting devices is located between another red and blue light-emitting devices arranged in two adjacent rows and two adjacent columns.

In some embodiments, in the first direction, a distance between light-emitting centers of any adjacent red and blue light-emitting devices is substantially the same; and in the second direction, a distance between light-emitting centers of any adjacent red and blue light-emitting devices is substantially the same.

In some embodiments, an overlapping portion of the second electrode, the photoelectric conversion portion and the fourth electrode forms a light-sensing device. The light-sensing device is disposed between a red light-emitting device and a blue light-emitting device adjacent along the first direction; or the light-sensing device is disposed between a red light-emitting device and a blue light-emitting device adjacent along the second direction.

In some embodiments, the plurality of red light-emitting devices and the plurality of blue light-emitting devices are divided into multiple light-emitting device groups, the light-emitting device groups each including a red light-emitting device and a blue light-emitting device adjacent in the second direction. The multiple light-emitting device groups include first sub-groups and second sub-groups, the first sub-groups and the second sub-groups being alternately arranged in the first direction, where a distance between a light-emitting center of a red light-emitting device and a light-emitting center of a blue light-emitting device in a first sub-group in the first sub-groups is less than a distance between a light-emitting center of a red light-emitting device and a light-emitting center of a blue light-emitting device in a second sub-group in the second sub-groups.

In some embodiments, an overlapping portion of the second electrode, the photoelectric conversion portion and the fourth electrode forms a light-sensing device. The light-sensing device is disposed between the red light-emitting device and the blue light-emitting device in the second sub-group; or the light-sensing device is disposed between two first sub-groups adjacent along the second direction; or the light-sensing device is disposed between a red light-emitting device and a blue light-emitting device adjacent along the first direction.

In some embodiments, a minimum distance between a boundary of the light-sensing device and a boundary of the red light-emitting device and a minimum distance between the boundary of the light-sensing device and a boundary of the blue light-emitting device are substantially equal.

In some embodiments, multiple light-sensing devices are disposed between red and blue light-emitting devices arranged in two adjacent rows and two adjacent columns, and second electrodes of the multiple light-sensing devices are electrically connected together.

In some embodiments, a line connecting light-emitting centers of the red light-emitting device and the blue light-emitting device on two opposite sides of the light-sensing device is a first connecting line; and a length of a portion of the light-sensing device overlapping with the first connecting line is a minimum dimension of the light-sensing device in a set direction, the set direction being substantially parallel to the first connecting line.

In another aspect, a display apparatus is provided. The display apparatus includes the display panel as described in any of the above embodiments.

In yet another aspect, a manufacturing method for a display panel is provided. The manufacturing method for the display panel includes: forming an anode layer on a substrate, the anode layer including a first electrode and a second electrode; forming a light-emitting portion on the first electrode and forming a photoelectric conversion portion on the second electrode; and forming a cathode layer on a side of the light-emitting portion and the photoelectric conversion portion away from the substrate, the cathode layer including a third electrode and a fourth electrode, where the third electrode is disposed opposite to the first electrode, and the second electrode is disposed opposite to the fourth electrode; along a direction perpendicular to the substrate, a thickness of the third electrode is greater than a thickness of the fourth electrode.

In some embodiments, forming the cathode layer on the side of the light-emitting portion and the photoelectric conversion portion away from the substrate, includes: forming a first electrode film, the first electrode film being a first sub-layer of the cathode layer; forming a first peeling portion on a side of the fourth electrode away from the substrate; forming a second electrode film, where adhesion between the first peeling portion and the first electrode film is less than adhesion between the first electrode film and the second electrode film; and peeling off a portion of the second electrode film overlapping with the first peeling portion, where a remaining portion of the second electrode film is a second sub-layer of the cathode layer.

In some embodiments, the cathode layer further includes an auxiliary cathode, and forming the cathode layer on the side of the light-emitting portion and the photoelectric conversion portion away from the substrate, further includes, after peeling off the portion of the second electrode film overlapping with the first peeling portion: forming a second peeling portion on a side of the third electrode away from the substrate; forming a third electrode film, where adhesion between the first peeling portion and the third electrode film, and adhesion between the second peeling portion and the third electrode film, are both less than adhesion between the third electrode film and the second electrode film; and peeling off portions of the third electrode film overlapping with the second peeling portion and the first peeling portion, where a remaining portion of the third electrode film is a third sub-layer of the cathode layer.

### BRIEF DESCRIPTION OF THE DRAWINGS

In order to describe technical solutions in the present disclosure more clearly, the accompanying drawings to be used in some embodiments of the present disclosure will be introduced briefly. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a cross-sectional view of a display apparatus, in accordance with some embodiments;

FIG. 3 is an exploded view of a display apparatus, in accordance with some embodiments;

FIG. 4 is a cross-sectional view taken along the A-A′ line in FIG. 3;

FIG. 5 is another cross-sectional view taken along the A-A′ line in FIG. 3;

FIG. 6 is a partially enlarged view of the region A in FIG. 4;

FIG. 7 is a top view of light-emitting devices and light-sensing devices, in accordance with some embodiments;

FIG. 8 is another top view of light-emitting devices and light-sensing devices, in accordance with some embodiments;

FIG. 9 is yet another top view of light-emitting devices and light-sensing devices, in accordance with some embodiments;

FIG. 10 is still another top view of light-emitting devices and light-sensing devices, in accordance with some embodiments;

FIG. 11 is yet still another top view of light-emitting devices and light-sensing devices, in accordance with some embodiments;

FIG. 12 is yet still another top view of light-emitting devices and light-sensing devices, in accordance with some embodiments;

FIG. 13 is a cross-sectional view taken along the B-B′ line in FIG. 9; and

FIG. 14 and FIG. 15 are each a flowchart of a manufacturing method for a display panel, in accordance with some embodiments.

### DETAILED DESCRIPTION

The technical solutions in some embodiments of the present disclosure will be described clearly and completely with reference to the accompanying drawings. Obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a/the plurality of (multiple)” means two or more unless otherwise specified.

In the description of some embodiments, the terms such as “coupled” and “connected” and derivatives thereof may be used. For example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

As used herein, the term “if” is, optionally, construed to mean “when” or “in a case where” or “in response to determining” or “in response to detecting”, depending on the context. Similarly, the phrase “if it is determined” or “if [a stated condition or event] is detected” is, optionally, construed to mean “in a case where it is determined” or “in response to determining” or “in a case where [the stated condition or event] is detected” or “in response to detecting [the stated condition or event]”, depending on the context. The use of “applicable to” or “configured to” herein means an open and inclusive expression, which does not exclude devices that are applicable to or configured to perform additional tasks or steps.

In addition, the use of the phrase “based on” is meant to be open and inclusive, since a process, step, calculation or other action that is “based on” one or more of the stated conditions or values may, in practice, be based on additional conditions or value beyond those stated.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

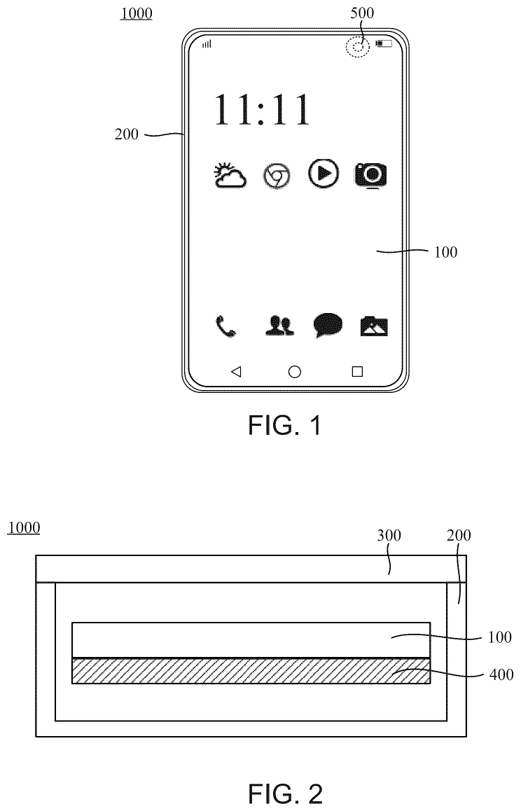

Referring to FIG. 1, some embodiments of the present disclosure provide a display apparatus 1000. The display apparatus 1000 may be any apparatus that can display an image whether in motion (e.g., video) or stationary (e.g., a still image), and whether textual or pictorial.

For example, the display apparatus 1000 may be any product or component having a display function, such as a television, a notebook computer, a tablet computer, a mobile phone, a personal digital assistant (PDA), a navigator, a wearable device, a virtual reality (VR) device, or the like.

In some embodiments, referring to FIG. 1, the display apparatus 1000 includes a display panel 100.

For example, as shown in FIG. 1 and FIG. 2, the display apparatus 1000 may further include a housing 200, a cover plate 300, a circuit board 400, a light-sensing device 500, and other electronic accessories.

As shown in FIG. 2, a longitudinal cross-section of the housing 200 may be, for example, U-shaped, the display panel 100 and the circuit board 400 are disposed within the housing 200, and the cover plate 300 is disposed at an opening of the housing 200.

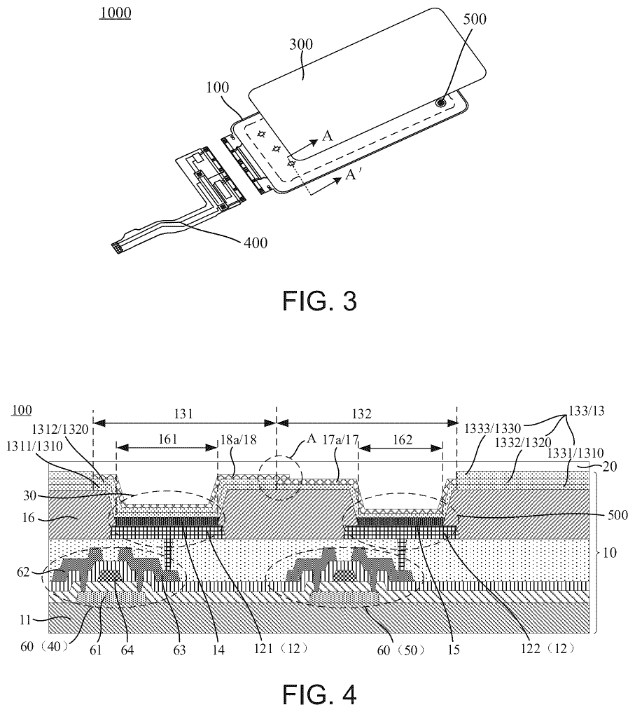

As shown in FIG. 2 and FIG. 3, the circuit board 400 may be bonded to the display panel 100 at an end of the display panel 100 and bent to a back side of the display panel 100, which is beneficial to the narrow frame design of the display apparatus 1000.

As shown in FIG. 1 and FIG. 3, the light-sensing device 500 may, for example, be integrated within the display panel 100 to realize a full-screen design. Here, the light-sensing device 500 includes at least one of: an infrared sensor, a proximity sensor, an eye-tracking module, and a face recognition module.

The type of the display panel 100 has a variety of options, which may be selected according to actual needs.

For example, the display panel 100 may be an organic light-emitting diode (OLED) display panel, or a quantum dot light-emitting diode (QLED) display panel, which is not specifically limited in the embodiments of the present disclosure.

Some embodiments of the present disclosure will be schematically described below by taking an example in which the display panel 100 is the OLED display panel.

In some embodiments, referring to FIG. 4, the display panel 100 includes a display substrate 10 and an encapsulation layer 20 for encapsulating the display substrate 10.

As shown in FIG. 4, the display substrate 10 has a light-exit side and a non-light-exit side that are disposed opposite to each other, and the encapsulation layer 20 is disposed on the light-exit side of the display substrate 10, that is, the upper side in FIG. 4.

It will be noted that the encapsulation layer 20 may be an encapsulation film or an encapsulation substrate. The encapsulation layer 20 is illustrated in FIG. 4 as an example of an encapsulation film.

In some embodiments, referring to FIG. 4, the display substrate 10 includes a substrate 11, an anode layer 12, a cathode layer 13, a light-emitting portion 14, and a photoelectric conversion portion 15.

The type of the substrate 11 has a variety of options, which may be selected according to actual needs.

For example, the substrate 11 may be a rigid substrate. By way of example, the rigid substrate may be, for example, a glass substrate or a polymethyl methacrylate (PMMA) substrate.

For example, the substrate 11 may be a flexible substrate. By way of example, the flexible substrate may be a polyethylene terephthalate (PET) substrate, a polyethylene naphthalate two formic acid glycol ester (PEN) substrate or a polyimide (PI) substrate.

As shown in FIG. 4, the anode layer 12 is disposed on a side (e.g., the upper side in FIG. 4) of the substrate 11. The anode layer 12 includes a first electrode 121 and a second electrode 122.

As shown in FIG. 4, the cathode layer 13 is disposed on a side of the anode layer 12 away from the substrate 11. The cathode layer 13 includes a third electrode 131 and a fourth electrode 132, in which the third electrode 131 is disposed opposite to the first electrode 121, and the fourth electrode 132 is disposed opposite to the second electrode 122.

As shown in FIG. 4, the light-emitting portion 14 is disposed between the first electrode 121 and the third electrode 131. In this case, an overlapping portion of the first electrode 121, the light-emitting portion 14 and the third electrode forms a light-emitting device. The first electrode 121 is an anode of the light-emitting device 30, and the third electrode 131 is a cathode of the light-emitting device 30.

As shown in FIG. 4, the photoelectric conversion portion 15 is disposed between the second electrode 122 and the fourth electrode 132. In this case, an overlapping portion of the second electrode 122, the photoelectric conversion portion 15, and the fourth electrode 132 forms a light-sensing device 500. The second electrode 122 is an anode of the light-sensing device 500 and the fourth electrode 132 is a cathode of the light-sensing device 500.

As shown in FIG. 4, the display substrate 10 further includes a pixel defining layer 16, and the pixel defining layer 16 is disposed on a side of the anode layer 12 away from the substrate 11.

As shown in FIG. 4, the pixel defining layer 16 is provided with a pixel opening 161 and a light-sensing opening 162. One light-emitting device 30 is located in one pixel opening 161, and one light-sensing device 500 is located in one light-sensing opening 162.

At present, how to increase the amount of light sensed by the light-sensing device without reducing the light-emitting efficiency of the light-emitting device is a problem that needs to be solved.

In light of this, in the embodiments of the present disclosure, along a direction perpendicular to the substrate 11, the thickness of the third electrode 131 is greater than the thickness of the fourth electrode 132. That is, the thickness of the cathode of the light-emitting device 30 is greater than the thickness of the cathode of the light-sensing device 500.

In this arrangement, the third electrode 131 can be designed to be relatively thick to enable the third electrode 131 to have a semi-transmissive and semi-reflective characteristic. In this way, a microcavity can be formed between the cathode and anode of the light-emitting device 30, thereby improving the light-emitting efficiency of the light-emitting device 30. Meanwhile, the fourth electrode 132 can be designed to be relatively thin to improve the light transmittance of the fourth electrode 132. In this way, the cathode of the light-sensing device 500 can have a relatively high light transmittance, which can increase the amount of light sensed by the light-sensing device 500 and improve the light sensitivity of the light-sensing device 500.

For example, referring to FIG. 4, along the direction perpendicular to the substrate 11, the cathode layer 13 includes a first sub-layer 1310 and a second sub-layer 1320, in which the first sub-layer 1310 is located on a side of the second sub-layer 1320 proximate to the substrate 11.

On this basis, along the direction perpendicular to the substrate 11, the third electrode 131 includes a first sub-electrode 1311 and a second sub-electrode 1312 arranged in a stack, in which the first sub-electrode 1311 is located in the first sub-layer 1310, and the second sub-electrode 1312 is located in the second sub-layer 1320. The fourth electrode 132 is located in the first sub-layer 1310.

In this case, the first sub-electrode 1311 of the third electrode 131 and the fourth electrode 132 can be made of the same material and formed in the same process step, thereby reducing production costs.

The thickness of the first sub-layer 1310 may be in a range of, for example, 2 nm to 8 nm. For example, the thickness of the first sub-layer 1310 is any one of 2 nm, 4 nm, 5 nm, 7 nm, and 8 nm.

The thickness of the second sub-layer 1320 may be in a range of, for example, 2 nm to 8 nm. For example, the thickness of the second sub-layer 1320 is any one of 2 nm, 4 nm, 5 nm, 7 nm, and 8 nm.

In addition, as shown in FIG. 4, the display panel 100 further includes a first peeling portion 17. The first peeling portion 17 is disposed on a side of the fourth electrode 132 away from the substrate 11, and the adhesion between the first peeling portion 17 and the second sub-layer 1320 is less than the adhesion between the first sub-layer 1310 and the second sub-layer 1320.

In this case, the first peeling portion 17 may be formed after forming the first sub-layer 1310 and before forming the second sub-layer 1320. In this way, no fine mask is required for the process of forming the second sub-layer 1320, and a portion of a second electrode film used for forming the second sub-layer 1320 overlapping with the first peeling portion 17 can be directly peeled off, so that the second sub-layer 1320 does not exist on the side of the fourth electrode 132 away from the substrate 11, thereby reducing the process difficulty of forming the third electrode 131 and the fourth electrode 132.

The thickness of the first peeling portion 17 may be in a range of, for example, 1 nm to 10 nm. For example, the thickness of the first peeling portion 17 is any one of 1 nm, 2 nm, 4 nm, 5 nm, 7 nm, 8 nm, and 10 nm.

It will be noted that the material of the first peeling portion 17 includes a light-transmitting material, and the transmittance of the light-transmitting material may be, for example, greater than or equal to 80%. For example, the material of the first peeling portion 17 includes at least one of 8-hydroxyquinoline lithium, N,N-biphenyl-N,N-di(9-phenyl-9H-carbazole-3-yl)diphenyl-4,4′-diamine, N(biphenyl-4-yl)9,9-dimethyl-N-(4(9-phenyl-9H-carbazole-3-yl)phenyl)-9H-fluorene-2-amine, and 2-(4-(9,10-di(naphthalene-2-yl)anthracene-2-yl)phenyl)-1-phenyl-1H-benzo-[D]imidazole.

It should be understood that the light-sensing device 500 should completely cover a region where the light-sensing opening 162 is located, so that the light-sensing device 500 can sense external ambient light in the region where the light-sensing opening 162 is located, thereby increasing a light-sensing area of the light-sensing device 500.

On this basis, referring to FIG. 4, the first peeling portion 17 covers a bottom of the light-sensing opening 162 and extends to a surface of the pixel defining layer 16 away from the substrate 11, so as to avoid the first peeling portion 17 being unable to completely cover the bottom of the light-sensing opening 162 due to process deviation. In this way, the first peeling portion 17 can completely cover the bottom of the light-sensing opening 162, avoiding the second sub-layer 1320 from being partially retained at the bottom of the light-sensing opening 162, so that the transmittance of the cathode layer 13 of the light-sensing device 500 in the entire region where the light-sensing opening 162 is located is relatively high, thereby increasing the amount of light sensed by the light-sensing device 500 and improving the light sensitivity of the light-sensing device 500.

In some embodiments, referring to FIG. 4, the cathode layer 13 further includes an auxiliary cathode 133, and the auxiliary cathode 133 is electrically connected to the third electrode 131, the fourth electrode 132, and a common voltage terminal.

It will be noted that the auxiliary cathode 133, the third electrode 131 and the fourth electrode 132 form a continuous whole-layer structure.

Along the direction perpendicular to the substrate 11, the thickness of the auxiliary cathode 133 is greater than the thickness of the third electrode 131. That is, the thickness of the auxiliary cathode 133 is greater than the thickness of the cathode of the light-emitting device 30, and greater than the thickness of the cathode of the light-sensing device 500.

In this arrangement, the auxiliary cathode 133 can be designed to be relatively thick to reduce the resistance of the auxiliary cathode 133. In this way, the voltage drop of a power supply voltage signal transmitted, through the auxiliary cathode 133, from the common voltage terminal to both the third electrode 131 and the fourth electrode 132 is relatively low, thereby improving brightness uniformity and reducing energy consumption.

For example, referring to FIG. 4, the cathode layer 13 further includes a third sub-layer 1330, in which the third sub-layer 1330 is located on a side of the second sub-layer 1320 away from the substrate 11.

On this basis, along the direction perpendicular to the substrate 11, the auxiliary cathode 133 includes a first conductive pattern 1331, a second conductive pattern 1332 and a third conductive pattern 1333 arranged in a stack, in which the first conductive pattern 1331 is located in the first sub-layer 1310, the second conductive pattern 1332 is located in the second sub-layer 1320, and the third conductive pattern 1333 is located in the third sub-layer 1330.

In this case, the first conductive pattern 1331 of the auxiliary cathode 133 and both the first sub-electrode 1311 of the third electrode 131 and the fourth electrode 132 can be made of the same material and formed in the same process step; and the second conductive pattern 1332 of the auxiliary cathode 133 and the second sub-electrode 1312 of the third electrode 131 can be made of the same material and formed in the same process step, thereby reducing production costs.

The thickness of the third sub-layer 1330 may be in a range of, for example, 1 nm to 10 nm. For example, the thickness of the third sub-layer 1330 is any one of 1 nm, 2 nm, 4 nm, 5 nm, 7 nm, 8 nm, and 10 nm.

In addition, as shown in FIG. 4, the display panel 100 further includes a second peeling portion 18. The second peeling portion 18 is disposed on a side of the third electrode 131 away from the substrate 11, and the adhesion between the second peeling portion 18 and the third sub-layer 1330 is less than the adhesion between the second sub-layer 1320 and the third sub-layer 1330.

In this case, the second peeling portion 18 may be formed after forming the second sub-layer 1320 and before forming the third sub-layer 1330. In this way, no fine mask is required for the process of forming the third sub-layer 1330, and portions of a third electrode film used for forming the third sub-layer 1330 overlapping with the first peeling portion 17 and the second peeling portion 18 can be directly peeled off, so that the third sub-layer 1330 does not exist on the side of the third electrode 131 and the fourth electrode 132 away from the substrate 11, thereby reducing the process difficulty of forming the third electrode 131, the fourth electrode 132 and the auxiliary cathode 133.

The thickness of the second peeling portion 18 may be in a range of, for example, 1 nm to 10 nm. For example, the thickness of the second peeling portion 18 is any one of 1 nm, 2 nm, 4 nm, 5 nm, 7 nm, 8 nm, and 10 nm.

It will be noted that the material of the second peeling portion 18 includes a light-transmitting material, and the transmittance of the light-transmitting material may be, for example, greater than or equal to 80%. For example, the material of the second peeling portion 18 includes at least one of 8-hydroxyquinoline lithium, N,N-biphenyl-N,N-di(9-phenyl-9H-carbazole-3-yl)diphenyl-4,4′-diamine, N(biphenyl-4-yl)9,9-dimethyl-N-(4 (9-phenyl-9H-carbazole-3-yl)phenyl)-9H-fluorene-2-amine, and 2-(4-(9,10-di(naphthalene-2-yl)anthracene-2-yl)phenyl)-1-phenyl-1H-benzo-[D]imidazole.

It should be understood that the light-emitting device 30 should completely cover a region where the pixel opening 161 is located, so that the light-emitting device 30 can emit light in the entire region where the pixel opening 161 is located, thereby improving the light-emitting efficiency.

On this basis, referring to FIG. 4, the second peeling portion 18 covers a bottom of the pixel opening 161 and extends to the surface of the pixel defining layer 16 away from the substrate 11, so as to avoid the second peeling portion 18 being unable to completely cover the bottom of the pixel opening 161 due to process deviation. In this way, the second peeling portion 18 can completely cover the bottom of the pixel opening 161, avoiding the third sub-layer 1330 from being partially retained at the bottom of the pixel opening 161, so that the cathode layer 13 of the light-emitting device 30 in the entire region where the pixel opening 161 is located has a semi-transparent and semi-reflective characteristic, thereby improving the light-emitting efficiency of the light-emitting device 30.

In addition, referring to FIG. 4, a portion of the first peeling portion 17 extending to the surface of the pixel defining layer 16 away from the substrate 11 is a first portion 17a, and a portion of the second peeling portion 18 extending to the surface of the pixel defining layer 16 away from the substrate 11 is a second portion 18a. An average distance between a boundary of the first portion 17a and the light-sensing opening 162 is less than an average distance between a boundary of the second portion 18a and the pixel opening 161.

In this arrangement, the average distance between the boundary of the second portion and the pixel opening 161 can be designed to be relatively large, so as to avoid the second peeling portion 18 being unable to completely cover a side wall of the pixel opening 161 due to process deviation. In this way, the second peeling portion 18 can completely cover the side wall of the pixel opening 161, avoiding the third sub-layer 1330 from being partially retained on the side wall of the pixel opening 161. As a result, a portion of the cathode layer 13 at the side wall of the pixel opening 161 is relatively thin, which is beneficial to the design of light output of the display apparatus 1000 at a large viewing angle.

Meanwhile, the average distance between the boundary of the first portion and the light-sensing opening 162 can be designed to be relatively small to reduce the area of the fourth electrode 132 and increase the proportion of the auxiliary cathode 133 in the cathode layer 13, thereby reducing the voltage drop, improving the brightness uniformity and reducing energy consumption.

For example, as shown in FIG. 4, the average distance between the boundary of the first portion and the light-sensing opening 162 is greater than or equal to 2 μm, and the average distance between the boundary of the second portion and the pixel opening 161 is less than 2 μm.

In some embodiments, referring to FIG. 7, the maximum area of an orthographic projection of the first peeling portion 17 on the substrate 11 is less than the maximum area of an orthographic projection of the second peeling portion 18 on the substrate 11.

For example, referring to FIG. 7, there are light-emitting devices 30 which include a plurality of red light-emitting devices 310, a plurality of blue light-emitting devices 320, a plurality of first green light-emitting devices 330, and a plurality of second green light-emitting devices 340.

Here, the light-emitting area of the blue light-emitting device 320 is greater than the light-emitting area of the red light-emitting device 310; the light-emitting area of the red light-emitting device 310 is greater than the light-emitting area of the first green light-emitting device 330; and the light-emitting area of the first green light-emitting device 330 is approximatively equal to the light-emitting area of the second green light-emitting device 340.

In this case, the area of an orthographic projection of a second peeling portion 18 located on a side of a third electrode 131 of the blue light-emitting device 320 away from the substrate 11 on the substrate 11 is the maximum area of the orthographic projection of the second peeling portion 18 on the substrate 11. That is, the area of the orthographic projection of the first peeling portion 17 on the substrate 11 is less than the area of the orthographic projection of the second peeling portion 18 on the side of the third electrode 131 of the blue light-emitting device 320 away from the substrate 11.

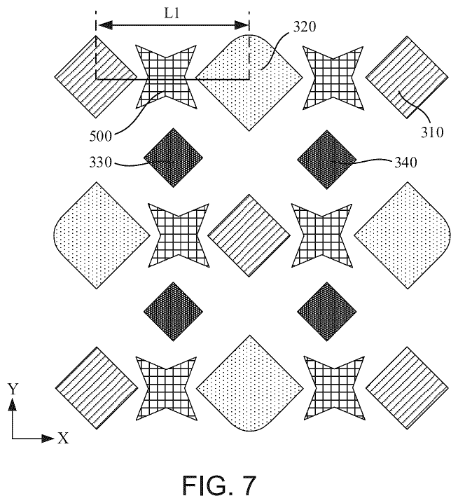

In some embodiments, as shown in FIG. 4 and FIG. 6, the first peeling portion 17 and the second peeling portion 18 partially overlap, and a portion of the second peeling portion 18 overlapping with the first peeling portion 17 is located on a side of the first peeling portion 17 away from the substrate 11.

In this case, the first peeling portion 17 and the second peeling portion 18 are formed in different process steps, respectively, and details can be referred to below.

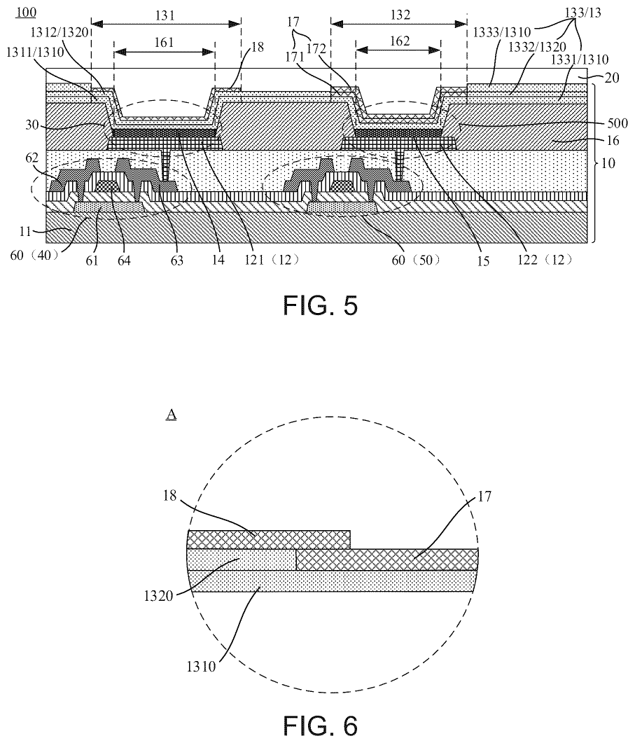

In some other embodiments, as shown in FIG. 5, the first peeling portion 17 includes a first sub-portion 171 and a second sub-portion 172 arranged in a stack, in which the first sub-portion 171 is located on a side of the second sub-portion 172 proximate to the substrate 11, and the second sub-portion 172 and the second peeling portion 18 are made of the same material and disposed in the same layer.

In this case, the second sub-portion 172 of the first peeling portion 17 and the second peeling portion 18 can be made of the same material and formed in the same process step, thereby reducing production costs. For details, please refer to the following. Moreover, the first peeling portion 17 is relatively thick, which is beneficial to the peeling of the third electrode film used for forming the third sub-layer 1330 from the first peeling portion 17.

In some embodiments, referring to FIG. 4, the display panel 100 may further include a functional layer. The functional layer includes a light-emitting functional portion and a photoelectric functional portion, in which the light-emitting functional portion is disposed between the first electrode 121 and the third electrode 161, and the photoelectric functional portion is disposed between the second electrode 122 and the fourth electrode 162.

In addition, the light-emitting functional layer may include at least one of: an electron transport layer (ETL), an electron injection layer (EIL), a hole transport layer (HTL), and a hole injection layer (HIL).

For example, along the direction perpendicular to the substrate 11 and away from the substrate 11, the functional layers include the hole injection layer, the hole transport layer, the electron transport layer, and the electron injection layer arranged in sequence. The light-emitting portion 14 and the photoelectric conversion portion 15 are located between the hole transport layer and the electron transport layer.

It can be seen from the above that the light-emitting functional portion of the light-emitting device 30 and the photoelectric functional portion of the light-sensing device 500 may be made of the same material and formed in the same process steps, thereby reducing production costs.

It will be appreciated that the arrangement of the light-emitting devices 30 is not unique.

In some embodiments, referring to FIG. 7, the plurality of light-emitting devices 30 include a plurality of red light-emitting devices 310, a plurality of blue light-emitting devices 320, a plurality of first green light-emitting devices 330, and a plurality of second green light-emitting devices 340.

As shown in FIG. 7, the plurality of red light-emitting devices 310 and the plurality of blue light-emitting devices 320 are arrayed into multiple rows and multiple columns, where each row includes multiple red light-emitting devices 310 and multiple blue light-emitting devices 320 which are arranged in a staggered manner along a first direction X, and each column includes multiple red light-emitting devices 310 and multiple blue light-emitting devices 320 which are arranged in a staggered manner along a second direction Y.

As shown in FIG. 7, the plurality of first green light-emitting devices 330 and the plurality of second green light-emitting devices 340 are arrayed into multiple rows and multiple columns, where each row includes multiple first green light-emitting devices 330 and multiple second green light-emitting devices 340 which are arranged in a staggered manner along the first direction X, each column includes multiple first green light-emitting devices 330 and multiple second green light-emitting devices 340 which are arranged in a staggered manner along the second direction Y. A first green light-emitting device 330 is located between red and blue light-emitting devices 310, 320 arranged in two adjacent rows and two adjacent columns, and a second green light-emitting device 340 is located between another red and blue light-emitting devices 310, 320 arranged in two adjacent rows and two adjacent columns.

In this arrangement, it is possible to effectively improve the display effect of the display panel 100, improve the display fineness, and reduce the appearance of edge jaggedness and display granularity.

In some examples, referring to FIG. 7, in the first direction X, a distance between light-emitting centers of any adjacent red and blue light-emitting devices 310, 320 is substantially the same; and in the second direction Y, a distance between light-emitting centers of any adjacent red and blue light-emitting devices 310, 320 is substantially the same.

As shown in FIG. 7, a light-sensing device 500 may be disposed between a red light-emitting device 310 and a blue light-emitting device 320 adjacent along the first direction X.

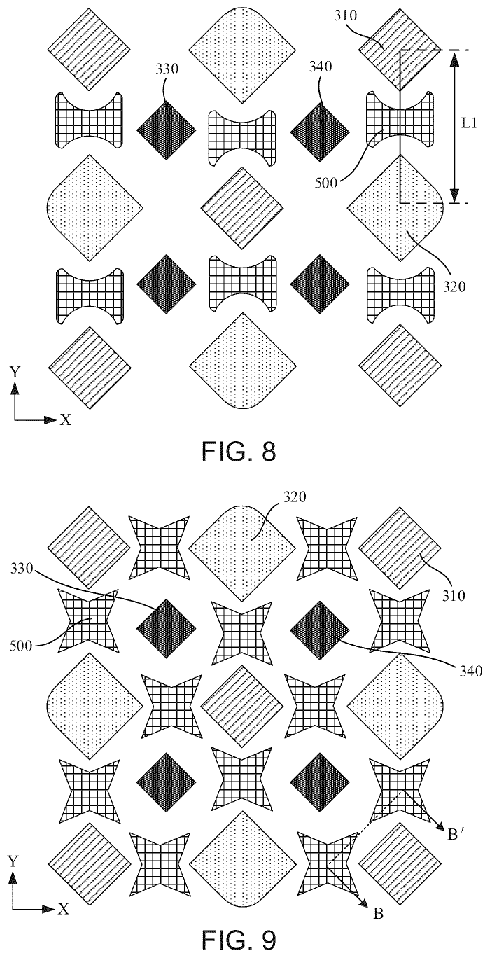

As shown in FIG. 8, a light-sensing device 500 may be disposed between a red light-emitting device 310 and a blue light-emitting device 320 adjacent along the second direction Y.

As shown in FIG. 9, a light-sensing device 500 may be disposed between a red light-emitting device 310 and a blue light-emitting device 320 adjacent along the first direction X, and another light-sensing device 500 may be between a red light-emitting device 310 and a blue light-emitting device 320 adjacent along the second direction Y.

In this case, referring to FIG. 9 and FIG. 13, multiple light-sensing devices 500 are disposed between red light-emitting devices 310 and blue light-emitting devices 320 which are arranged in two adjacent rows and two adjacent columns. On this basis, second electrodes 122 of the multiple light-sensing devices 500 may be electrically connected together. In this way, the multiple light-sensing devices 500 may act as a light-sensing unit to increase the number of signals sensed by the light-sensing circuit 50 as mentioned below, and to improve the light sensitivity.

Referring to FIG. 4, the display panel 100 further includes a pixel driving circuit 40 and a light-sensing circuit 50, and the pixel driving circuit 40 and the light-sensing circuit 50 each include a thin film transistor 60. The thin film transistor 60 includes a semiconductor channel 61, a source 62, a drain 63, and a gate 64, in which the source 62 and the drain 63 are both in contact with the semiconductor channel 61.

It will be noted that the source 62 and drain 63 described above are interchangeable, that is, “62” in FIG. 4 indicates the drain while “63” in FIG. 4 indicates the source.

As shown in FIG. 4, the anode (the first electrode 121) of the light-emitting device 30 is electrically connected to a source 62 or drain 63 of a thin film transistor 60 of the pixel driving circuit 40. The anode 122 (the second electrode 122) is electrically connected to a source 62 or drain 63 of a thin film transistor 60 of the light-sensing circuit 50. FIG. 4 illustrates an example in which the first electrode 121 is electrically connected to the drain 63 of the thin film transistor 60 of the pixel driving circuit 40, and the second electrode 122 is electrically connected to the drain 63 of the thin film transistor 60 of the light-sensing circuit 50.

Here, second electrodes 122 of multiple light-sensing devices 500 are electrically connected together, that is, the second electrodes 122 of the multiple light-sensing devices 500 are electrically connected to a same light-sensing circuit 50. For example, the second electrodes 122 of the multiple light-sensing devices 500 are electrically connected to a source 62 of a thin film transistor 60 of the light-sensing circuit 50.

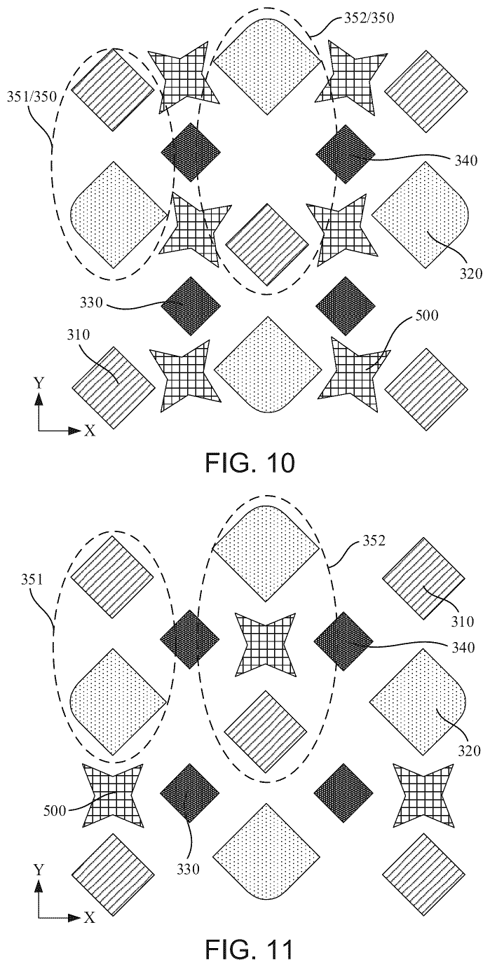

In some other examples, referring to FIG. 10, the plurality of red light-emitting devices 310 and the plurality of blue light-emitting devices 320 are divided into multiple light-emitting device groups 350, where the light-emitting device group 350 includes a red light-emitting device 310 and a blue light-emitting device 320 adjacent in the second direction Y.

The multiple light-emitting device groups 350 include first sub-groups 351 and second sub-groups 352, where the first sub-groups 351 and the second sub-groups 352 are alternately arranged in the first direction X. Moreover, a distance between a light-emitting center of a red light-emitting device 310 and a light-emitting center of a blue light-emitting device 320 in the first sub-group 351 is less than a distance between a light-emitting center of a red light-emitting device 310 and a light-emitting center of a blue light-emitting device 320 in a second sub-group 352.

As shown in FIG. 10, a light-sensing device 500 is disposed between a red light-emitting device 310 and a blue light-emitting device 320 adjacent along the first direction X.

As shown in FIG. 11, a light-sensing device 500 is disposed between a red light-emitting device 310 and a blue light-emitting device 320 in a second sub-group 352, and another light-sensing device 500 is disposed between two first sub-groups 351 adjacent along the second direction Y.

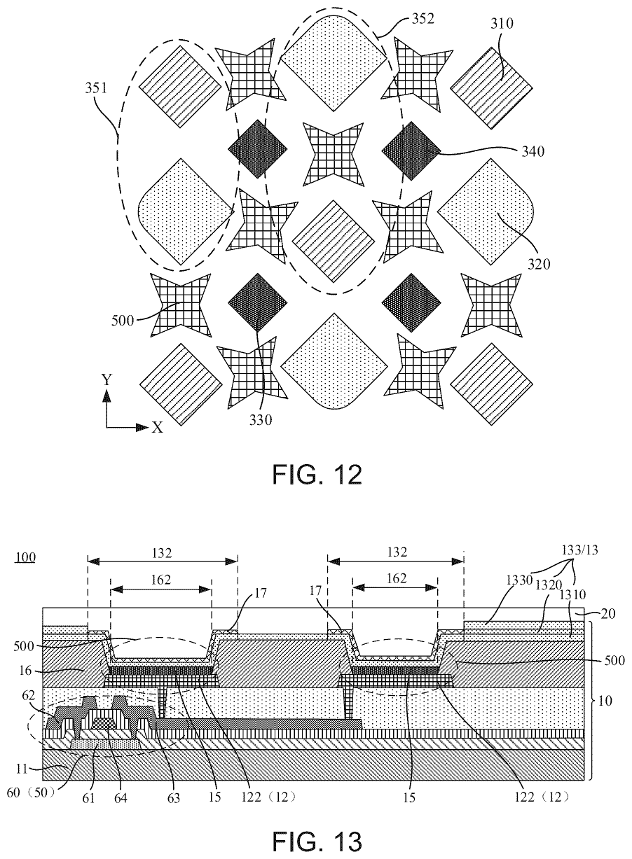

As shown in FIG. 12, a light-sensing device 500 is disposed between a red light-emitting device 310 and a blue light-emitting device 320 adjacent along the first direction X, another light-sensing device 500 is disposed between a red light-emitting device 310 and a blue light-emitting device 320 in a second sub-group 352, and yet another light-sensing device 500 is disposed between two first sub-groups 351 adjacent along the second direction Y.

In this case, referring to FIG. 9, FIG. 12 and FIG. 13, multiple light-sensing devices 500 are disposed between red light-emitting devices 310 and blue light-emitting devices 320 which are arranged in two adjacent rows and two adjacent columns. On this basis, second electrodes 122 of the multiple light-emitting devices 500 may be electrically connected together.

Here, the second electrodes 122 of the multiple light-sensing devices 500 are electrically connected together, that is, the second electrodes 122 of the multiple light-sensing devices 500 are electrically connected to a same light-sensing circuit 50. For example, the second electrodes 122 of the multiple light-sensing devices 500 are electrically connected to a source 62 of a thin film transistor 60 of the light-sensing circuit 50.

In some embodiments, referring to FIG. 7, the minimum distance between a boundary of a light-sensing device 500 and a boundary of a red light-emitting device 310 and a minimum distance between the boundary of the light-sensing device 500 and a boundary of a blue light-emitting device 320 are substantially equal, so as to facilitate the preparation of the fine mask required in the process of forming the light-sensing device 500.

In some embodiments, as shown in FIG. 7 and FIG. 8, a line connecting light-emitting centers of a red light-emitting device 310 and a blue light-emitting device 320 on two opposite sides of a light-sensing device 500 is a first connecting line L1.

The length of a portion of the light-sensing device 500 overlapping with the first connecting line L1 is the minimum dimension of the light-sensing device 500 in a set direction, where the set direction is substantially parallel to the first connecting line L1. By setting in this way, the light-sensing area of the light-sensing device 500 can be increased, thereby increasing the amount of light sensed by the light-sensing device 500 and improving the light sensitivity of the light-sensing device 500.

For example, as shown in FIG. 8, an orthographic projection of the light-sensing device 500 on the substrate 11 has a pillow shape that is narrow in the middle and wide on both sides, and the center line of the pillow is located on the first connecting line L1. For example, as shown in FIG. 7, the orthographic projection of the light-sensing device 500 on the substrate 11 has a four-pointed star shape, and one of the two shortest diagonals of the four-pointed star is located on the first connecting line L1.

It will be noted that the orthographic projection of the light-sensing device 500 on the substrate 11 may be any of other shapes, which are not specifically limited in the embodiments of the present disclosure.

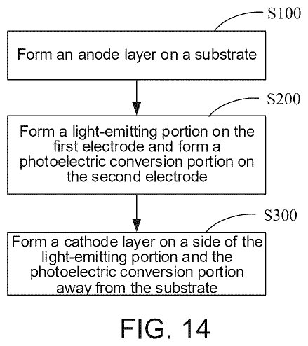

Some embodiments of the present disclosure provide a manufacturing method for a display panel, referring to FIG. 14, which includes steps S100 to S300.

In S100, an anode layer 12 is formed on a substrate 11.

In the above step, an anode film may be first formed by a sputtering or evaporation process; then, a photoresist pattern is formed on the upper surface of the anode film by coating, exposure and development processes, and based on the photoresist pattern, the anode film is etched by etching process to form the anode layer 12; and finally, the photoresist pattern is peeled off.

As shown in FIG. 4, the anode layer 12 includes a first electrode 121 and a second electrode 122. The structures of the first electrode 121 and the second electrode 122 can be referred to above, which will not be described in detail in the embodiments of the present disclosure.

In S200, a light-emitting portion 14 is formed on the first electrode 121 and a photoelectric conversion portion 15 is formed on the second electrode 122.

In the above step, the light-emitting portion 14 and the photoelectric conversion portion 15 may be formed separately by using an evaporation process and a fine mask. Here, as shown in FIG. 4, the structures of the light-emitting portion 14 and the photoelectric conversion portion 15 can be referred to above, which will not be described in detail in the embodiments of the present disclosure.

In S300, a cathode layer 13 is formed on a side of the light-emitting portion 14 and the photoelectric conversion portion 15 away from the substrate 11.

In the above step, as shown in FIG. 4, the cathode layer 13 includes a third electrode 131 and a fourth electrode 132, in which the third electrode 131 is disposed opposite to the first electrode 121, and the second electrode 122 is disposed opposite to the fourth electrode 132. Along a direction perpendicular to the substrate 11, the thickness of the third electrode 131 is greater than the thickness of the fourth electrode 132.

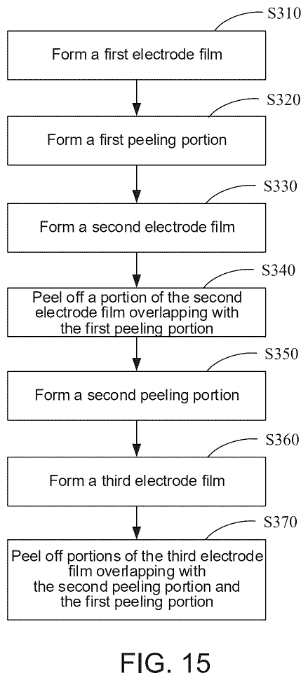

In some embodiments, referring to FIG. 15, S300 includes steps S310 to S340.

In S310, a first electrode film is formed.

In the above step, the first electrode film may be formed using a sputtering or evaporation process. Here, the first electrode film is the first sub-layer 1310 of the cathode layer 13 mentioned above.

In S320, a first peeling portion 17 is formed.

In the above step, the first peeling portion 17 may be formed by using an evaporation process and a fine mask. The first peeling portion 17 is disposed on a side of the fourth electrode 132 away from the substrate 11.

In S330, a second electrode film is formed.

In the above step, the second electrode film may be formed by a sputtering or evaporation process. The adhesion between the first peeling portion 17 and the first electrode film is less than the adhesion between the first electrode film and the second electrode film, so as to facilitate the peeling of a portion of the second electrode film overlapping with the first peeling portion 17 in S340.

In S340, the portion of the second electrode film overlapping with the first peeling portion 17 is peeled off.

In the above step, the remaining portion of the second electrode film is the second sub-layer 1320 of the cathode layer 13.

In some embodiments, referring to FIG. 4, the cathode layer 13 further includes an auxiliary cathode 133, and the thickness of the auxiliary cathode 133 is greater than the thickness of the third electrode 131. In this case, as shown in FIG. 15, S300 further includes: steps S350 to S370 after S340.

In S350, a second peeling portion 18 is formed.

In the above step, the second peeling portion 18 may be formed by using an evaporation process and a fine mask. The second peeling portion 18 is disposed on a side of the third electrode 131 away from the substrate 11.

In S360, a third electrode film is formed.

In the above step, the third electrode film may be formed by using an evaporation process. Here, the adhesion between the first peeling portion 17 and the third electrode film, and the adhesion between the second peeling portion and the third electrode film, are both less than the adhesion between the third electrode film and the second electrode film, so as to facilitate the peeling of portions of the third electrode film overlapping with the second peeling portion 18 and the first peeling portion 17 in S370.

In S370, the portions of the third electrode film overlapping with the second peeling portion 18 and the first peeling portion 17 are peeled.

In the above step, the reaming portion of the third electrode film is the third sub-layer 1330 of the cathode layer 13.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a substrate;
an anode layer, disposed on a side of the substrate and including a first electrode and a second electrode;
a cathode layer, disposed on a side of the anode layer away from the substrate and including a third electrode and a fourth electrode, wherein the third electrode is disposed opposite to the first electrode, and the fourth electrode is disposed opposite to the second electrode; and along a direction perpendicular to the substrate, a thickness of the third electrode is greater than a thickness of the fourth electrode;
a light-emitting portion, disposed between the first electrode and the third electrode; and
a photoelectric conversion portion, disposed between the second electrode and the fourth electrode.

2. The display panel according to claim 1, wherein along the direction perpendicular to the substrate, the cathode layer includes a first sub-layer and a second sub-layer, the first sub-layer being located on a side of the second sub-layer proximate to the substrate; and
along the direction perpendicular to the substrate, the third electrode includes a first sub-electrode and a second sub-electrode arranged in a stack, the first sub-electrode being located in the first sub-layer, and the second sub-electrode being located in the second sub-layer; and the fourth electrode is located in the first sub-layer.

3. The display panel according to claim 2, further comprising:
a first peeling portion, disposed on a side of the fourth electrode away from the substrate, wherein adhesion between the first peeling portion and the second sub-layer is less than adhesion between the first sub-layer and the second sub-layer.

4. The display panel according to claim 1, wherein the cathode layer further includes an auxiliary cathode, the auxiliary cathode being electrically connected to the third electrode, the fourth electrode and a common voltage terminal in the display panel; and along the direction perpendicular to the substrate, a thickness of the auxiliary cathode is greater than a thickness of the third electrode.

5. The display panel according to claim 4, wherein the cathode layer includes a first sub-layer, a second sub-layer and a third sub-layer, the first sub-layer being located on a side of the second sub-layer proximate to the substrate, and the third sub-layer being located on a side of the second sub-layer away from the substrate; and
along the direction perpendicular to the substrate, the auxiliary cathode includes a first conductive pattern, a second conductive pattern and a third conductive pattern arranged in a stack, the first conductive pattern being located in the first sub-layer, the second conductive pattern being located in the second sub-layer, and the third conductive pattern being located in the third sub-layer.

6. The display panel according to claim 5, further comprising:
a second peeling portion, disposed on a side of the third electrode away from the substrate, wherein adhesion between the second peeling portion and the third sub-layer is less than adhesion between the second sub-layer and the third sub-layer.

7. The display panel according to claim 6, further comprising a first peeling portion, wherein the first peeling portion and the second peeling portion partially overlap, and a portion of the second peeling portion overlapping with the first peeling portion is located on a side of the first peeling portion away from the substrate.

8. The display panel according to claim 6, further comprising a first peeling portion, wherein the first peeling portion includes a first sub-portion and a second sub-portion arranged in a stack, the first sub-portion being located on a side of the second sub-portion proximate to the substrate, and the second sub-portion and the second peeling portion being made of a same material and disposed in a same layer.

9. The display panel according to claim 6, further comprising a first peeling portion, a maximum area of an orthographic projection of the first peeling portion on the substrate being less than a maximum area of an orthographic projection of the second peeling portion on the substrate.

10. The display panel according to claim 6, further comprising:
a first peeling portion; and
a pixel defining layer, disposed on a side of the anode layer away from the substrate, the pixel defining layer being provided with a pixel opening and a light-sensing opening;
wherein the first peeling portion covers a bottom of the light-sensing opening and extends to a surface of the pixel defining layer away from the substrate; and the second peeling portion covers a bottom of the pixel opening and extends to the surface of the pixel defining layer away from the substrate; and
a portion of the first peeling portion extending to the surface of the pixel defining layer away from the substrate is a first portion, and a portion of the second peeling portion extending to the surface of the pixel defining layer away from the substrate is a second portion; and an average distance between a boundary of the first portion and the light-sensing opening is less than an average distance between a boundary of the second portion and the pixel opening.

11. (canceled)

12. The display panel according to claim 1, wherein an overlapping portion of the first electrode, the light-emitting portion and the third electrode forms a light-emitting device; and the display panel comprises a plurality of light-emitting devices including a plurality of red light-emitting devices, a plurality of blue light-emitting devices, a plurality of first green light-emitting devices, and a plurality of second green light-emitting devices;
the plurality of red light-emitting devices and the plurality of blue light-emitting devices are arrayed into multiple rows and multiple columns, each row includes multiple red light-emitting devices and multiple blue light-emitting devices that are arranged in a staggered manner along a first direction, and each column includes multiple red light-emitting devices and multiple blue light-emitting devices that are arranged in a staggered manner along a second direction; and
the plurality of first green light-emitting devices and the plurality of second green light-emitting devices are arrayed into multiple rows and multiple columns, each row includes multiple first green light-emitting devices and multiple second green light-emitting devices that are arranged in a staggered manner along the first direction, each column includes multiple first green light-emitting devices and multiple second green light-emitting devices that are arranged in a staggered manner along the second direction; and a first green light-emitting device in the plurality of first green light-emitting devices is located between red and blue light-emitting devices arranged in two adjacent rows and two adjacent columns, and a second green light-emitting device in the plurality of second green light-emitting devices is located between another red and blue light-emitting devices arranged in two adjacent rows and two adjacent columns.

13. The display panel according to claim 12, wherein in the first direction, a distance between light-emitting centers of any adjacent red and blue light-emitting devices is substantially the same; and in the second direction, a distance between light-emitting centers of any adjacent red and blue light-emitting devices is substantially the same.

14. The display panel according to claim 13, wherein an overlapping portion of the second electrode, the photoelectric conversion portion and the fourth electrode forms a light-sensing device; and
the light-sensing device is disposed between a red light-emitting device and a blue light-emitting device adjacent along the first direction; or the light-sensing device is disposed between a red light-emitting device and a blue light-emitting device adjacent along the second direction.

15. The display panel according to claim 12, wherein the plurality of red light-emitting devices and the plurality of blue light-emitting devices are divided into multiple light-emitting device groups, the light-emitting device groups each including a red light-emitting device and a blue light-emitting device adjacent in the second direction; and
the multiple light-emitting device groups include first sub-groups and second sub-groups, the first sub-groups and the second sub-groups being alternately arranged in the first direction, wherein a distance between a light-emitting center of a red light-emitting device and a light-emitting center of a blue light-emitting device in a first sub-group in the first sub-groups is less than a distance between a light-emitting center of a red light-emitting device and a light-emitting center of a blue light-emitting device in a second sub-group in the second sub-groups.

16. The display panel according to claim 15, wherein an overlapping portion of the second electrode, the photoelectric conversion portion and the fourth electrode forms a light-sensing device; and
the light-sensing device is disposed between the red light-emitting device and the blue light-emitting device in the second sub-group; or the light-sensing device is disposed between two first sub-groups adjacent along the second direction; or the light-sensing device is disposed between a red light-emitting device and a blue light-emitting device adjacent along the first direction.

17. The display panel according to claim 14, wherein a minimum distance between a boundary of the light-sensing device and a boundary of the red light-emitting device and a minimum distance between the boundary of the light-sensing device and a boundary of the blue light-emitting device are substantially equal; and/or
multiple light-sensing devices are disposed between red and blue light-emitting devices arranged in two adjacent rows and two adjacent columns, and second electrodes of the multiple light-sensing devices are electrically connected together; and/or
a line connecting light-emitting centers of the red light-emitting device and the blue light-emitting device on two opposite sides of the light-sensing device is a first connecting line; and a length of a portion of the light-sensing device overlapping with the first connecting line is a minimum dimension of the light-sensing device in a set direction, the set direction being substantially parallel to the first connecting line.

18.-19. (canceled)

20. A display apparatus, comprising the display panel according to claim 1.

21. A manufacturing method for a display panel, comprising:
forming an anode layer on a substrate, the anode layer including a first electrode and a second electrode;
forming a light-emitting portion on the first electrode and forming a photoelectric conversion portion on the second electrode; and
forming a cathode layer on a side of the light-emitting portion and the photoelectric conversion portion away from the substrate, the cathode layer including a third electrode and a fourth electrode, wherein the third electrode is disposed opposite to the first electrode, and the second electrode is disposed opposite to the fourth electrode; along a direction perpendicular to the substrate, a thickness of the third electrode is greater than a thickness of the fourth electrode.

22. The manufacturing method for the display panel according to claim 21, wherein forming the cathode layer on the side of the light-emitting portion and the photoelectric conversion portion away from the substrate, includes:
forming a first electrode film, the first electrode film being a first sub-layer of the cathode layer;
forming a first peeling portion on a side of the fourth electrode away from the substrate;
forming a second electrode film, wherein adhesion between the first peeling portion and the first electrode film is less than adhesion between the first electrode film and the second electrode film; and
peeling off a portion of the second electrode film overlapping with the first peeling portion, wherein a remaining portion of the second electrode film is a second sub-layer of the cathode layer.

23. The manufacturing method for the display panel according to claim 22, wherein the cathode layer further includes an auxiliary cathode, and forming the cathode layer on the side of the light-emitting portion and the photoelectric conversion portion away from the substrate, further includes, after peeling off the portion of the second electrode film overlapping with the first peeling portion:
forming a second peeling portion on a side of the third electrode away from the substrate;
forming a third electrode film, wherein adhesion between the first peeling portion and the third electrode film, and adhesion between the second peeling portion and the third electrode film, are both less than adhesion between the third electrode film and the second electrode film; and
peeling off portions of the third electrode film overlapping with the second peeling portion and the first peeling portion, wherein a remaining portion of the third electrode film is a third sub-layer of the cathode layer.
